(19) United States
(12) Patent Application Publication
(10) Pub. No.: US 2026/0227589 A1
(43) Pub. Date: Aug. 6, 2026

(54) PHOTONIC DEVICE WITH PLUGGABLE OPTICAL COUPLER

(71) Applicant: Lightmatter, Inc., Boston, MA (US)

(72) Inventors: Sufi Ahmed, Chandler, AZ (US); Omkar Karhade, Chandler, AZ (US)

(73) Assignee: Lightmatter, Inc., Boston, MA (US)

(21) Appl. No.: 19/529,021

(22) Filed: Feb. 3, 2026

Related U.S. Application Data
(60) Provisional application No. 63/753,834, filed on Feb. 4, 2025.

(51) Int. Cl. G02B 6/42

(52) U.S. Cl. CPC G02B 6/4292; G02B 6/4212

(57) ABSTRACT

Described herein are photonic devices and methods of manufacturing the same. The photonic devices include a photonic integrated circuit (PIC) disposed on a substrate and a socket configured to receive a pluggable optical coupler to couple the PIC to one or more optical fibers. Manufacturing the photonic devices may include removing a portion of the PIC to expose through-silicon-vias (TSVs) of the PIC, coupling electronic integrated circuits (EIC) to the PIC, and forming a mold around portions of the EICs. The architecture of the photonic devices enables pluggable fiber array units in multi-die configurations while maintaining low optical loss through wafer-level assembly.

### CROSS-REFERENCE TO RELATED APPLICATIONS

This application claims the benefit under 35 U.S.C. § 119(e) of U.S. Provisional Application Ser. No. 63/753,834, filed on Feb. 4, 2025, under Attorney Docket No. L0858.70118US00 and entitled “PHOTONIC DEVICE WITH PLUGGABLE OPTICAL COUPLER,” which is hereby incorporated herein by reference in its entirety.

### BACKGROUND

Photonic devices employ photonic integrated circuits to route optical signals to different components on and off the photonic device. Photonic integrated circuits (PICs) are devices that integrate multiple photonic components, such as waveguides, detectors, switches and modulators, on a single substrate. Similar to how electronic integrated circuits (EICs) manipulate electrical signals, PICs manipulate light to transmit, process and detect information at high speeds and with low power consumption. PICs are increasingly used in applications such as optical communications, data centers, sensing and quantum computing.

### SUMMARY

The development of silicon photonic integrated circuits (PICs) with multiple top dies and multi-reticle PICs using pluggable optical couplers represents a significant advancement in silicon photonics technology. This architecture addresses current limitations in assembly flow, enabling the integration of pluggable couplers and enhancing optical performance for a wide range of applications, including telecommunications and data centers.

In some aspects, the techniques described herein relate to a photonic device, including: a substrate; an electro-optical assembly including: a photonic integrated circuit (PIC) disposed on the substrate, the PIC having a first surface facing the substrate and a second surface opposite the first surface; an electronic integrated circuit (EIC) coupled to the PIC at the second surface; an optical assembly having an optical fiber; and an optical coupler disposed on the first surface of the PIC configured to optically couple the electro-optical assembly with the optical fiber when the optical assembly is coupled with the electro-optical assembly.

In some aspects, the techniques described herein relate to a photonic device, wherein the optical coupler is secured within a cavity on the first surface of the PIC with index-matching adhesive.

In some aspects, the techniques described herein relate to a photonic device, further including an encapsulation structure at least partially surrounding the EIC.

In some aspects, the techniques described herein relate to a photonic device, wherein the optical assembly is configured to be removably couplable from the electro-optical assembly.

In some aspects, the techniques described herein relate to a photonic device, further including a socket disposed adjacent the first surface of the PIC, wherein the optical assembly is configured to be removably couplable from the electro-optical assembly by engaging with the socket to optically couple the optical fiber with the optical coupler.

In some aspects, the techniques described herein relate to a photonic device, wherein the socket is disposed on the electro-optical assembly.

In some aspects, the techniques described herein relate to a photonic device, wherein the socket is disposed on the substrate.

In some aspects, the techniques described herein relate to a photonic device, further including an integrated heat spreader coupled with the EIC.

In some aspects, the techniques described herein relate to a photonic device, wherein the optical assembly includes a pluggable fiber array unit.

In some aspects, the techniques described herein relate to a method for manufacturing a photonic device, the method including: receiving a photonic integrated circuit (PIC), the PIC having a first surface and a second surface opposite the first surface; forming an electro-optical assembly by coupling an electronic integrated circuit (EIC) to the PIC at the second surface; securing an optical coupler to the first surface; securing the electro-optical assembly to a substrate at the first surface; and coupling an optical assembly to the electro-optical assembly, the optical assembly having an optical fiber, wherein the optical coupler is configured to optically couple the optical fiber to the electro-optical assembly when the optical assembly is coupled with the electro-optical assembly.

In some aspects, the techniques described herein relate to a method, wherein forming the electro-optical assembly includes: etching the PIC at the second surface to expose ends of through silicon vias (TSVs) extending through the PIC; and disposing conductive bumps at the exposed ends of the TSVs, wherein the EIC is coupled with the PIC via the conductive bumps.

In some aspects, the techniques described herein relate to a method, wherein forming the electro-optical assembly further includes: forming a redistribution layer including conductive traces extending between the TSVs; and disposing the conductive bumps on the redistribution layer.

In some aspects, the techniques described herein relate to a method, wherein forming the electro-optical assembly further includes: forming an encapsulation structure to at least partially surround the EIC.

In some aspects, the techniques described herein relate to a method, wherein forming the electro-optical assembly further includes: grinding the encapsulation structure to expose a surface of the EIC facing away from the PIC; and attaching a heat sink to the exposed surface of the EIC.

In some aspects, the techniques described herein relate to a method, wherein securing the optical coupler to the first surface includes: disposing adhesive within a cavity on the first surface; placing the optical coupler within the cavity; and curing the adhesive.

In some aspects, the techniques described herein relate to a method, wherein securing the optical coupler to the first surface further includes: plasma cleaning at least the cavity on the first surface prior to disposing the adhesive within the cavity.

In some aspects, the techniques described herein relate to a method, wherein coupling an optical assembly to the electro-optical assembly includes: removably coupling the optical assembly to the electro-optical assembly.

In some aspects, the techniques described herein relate to a method, wherein removably coupling the optical assembly to the electro-optical assembly includes: inserting the optical assembly into a socket disposed on the substrate.

In some aspects, the techniques described herein relate to a method, wherein forming the electro-optical assembly includes: forming a plurality of electro-optical assemblies as an integrated wafer.

In some aspects, the techniques described herein relate to a method, wherein forming the electro-optical assembly further includes: dicing the integrated wafer to obtain individual electro-optical assemblies.

### BRIEF DESCRIPTION OF THE DRAWINGS

Various aspects and embodiments of the application will be described with reference to the following figures. It should be appreciated that the figures are not necessarily drawn to scale. Items appearing in multiple figures are indicated by the same reference number in the figures in which they appear.

FIG. 1 illustrates a cross-sectional side view of a packaged photonic device, according to some embodiments.

FIGS. 2A-2H illustrate an example process for forming the photonic integrated circuit (PIC) of a photonic device, according to some embodiments. FIG. 2A depicts a step of receiving a PIC having an etched cavity. FIG. 2B depicts a step of attaching pads to exposed ends of through silicon vias (TSVs) of the PIC. FIG. 2C depicts a step of attaching a first temporary carrier to the PIC. FIG. 2D depicts a step of etching the PIC to reveal the TSVs. FIG. 2E depicts a passivation step. FIG. 2F depicts a step of depositing a redistribution layer on the passivation layer. FIG. 2G depicts a second passivation step. FIG. 2H depicts a step for depositing bumps on the PIC in electrical contact with the redistribution layer.

FIGS. 3A-3F illustrate an example process for forming an electro-optical assembly of a photonic device, according to some embodiments. FIG. 3A depicts a step of coupling electronic integrated circuit(s) (EICs) to a PIC to form the electro-optical assembly. FIG. 3B depicts an underfill step to secure the EIC(s) to the PIC). FIG. 3C depicts a step in which an encapsulation structure is deposited to at least partially surround the EICs. FIG. 3D depicts a step in which the encapsulation structure is ground to reveal the EICs. FIG. 3E depicts a step in which a second temporary carrier is attached to the electro-optical assembly. FIG. 3F depicts a step in which the first temporary carrier is removed from the PIC of the electro-optical assembly.

FIGS. 4A-4F illustrate an example process for optical coupler attachment to the electro-optical assembly formed by the process of FIGS. 3A-F, according to some embodiments. FIG. 4A depicts a cleaning step of the cavity of the PIC. FIG. 4B depicts a step in which adhesive is dispensed in the cavity. FIG. 4C depicts an attachment step of an optical coupler to the PIC within the cavity. FIG. 4D depicts an adhesive curing step. FIG. 4E depicts a step in which the second temporary carrier is removed from the assembly. FIG. 4F depicts a step in which the assembly is attached to a mount for subsequent dicing into individual electro-optical assemblies.

FIGS. 5A-5H illustrate an example process for forming photonic devices having electro-optical assemblies formed by processes of FIGS. 4A-F, according to some embodiments. FIG. 5A depicts a dicing step in which individual electro-optical assemblies are diced from a wafer of multiple assemblies. FIG. 5B illustrates a step in which the individual assemblies are loaded onto a matrix tray. FIG. 5C illustrates an attached step of the individual assemblies to a substrate. FIG. 5D illustrates a cleaning step in which solder flux and other manufacturing by-products are removed from the assemblies. FIG. 5E illustrates an underfill step to secure the assemblies to the substrate. FIG. 5F illustrates a step in which an integrated heat spreader is attached to the assemblies. FIG. 5G illustrates a step in which a socket configured to receive an optical assembly is attached to the electro-optical assemblies. FIG. 5H illustrates a step in which the optical assembly having an optical fiber is optically coupled to the optical coupler.

### DETAILED DESCRIPTION

Embodiments described herein provide examples of photonic device architectures and assembly processes that enable the attachment of top dies without obstructing the fiber coupling regions of the photonic devices, thereby facilitating the integration of pluggable couplers in multi-die and multi-reticle scenarios.

Silicon photonic integrated circuits are increasingly important for telecommunications and data center applications. Current assembly flows utilize V-groove fiber attach or pluggable fiber array units (FAU) but are limited to single top die/single reticle through silicon via (TSV) PIC configurations. This limitation arises because the mold process used for multiple top die configurations inadvertently covers the V-groove or cavity used for attaching the pluggable coupler, which necessitates dicing to expose the PIC's waveguides.

Conventional solutions involve face-to-face bonding of the PIC and multiple top dies using lead-free reflow, followed by molding and dicing to expose the PIC's waveguides. However, because of the molding process, the conventional assembly flow cannot effectively be extended to accommodate multiple top die or multi-reticle configurations. As such, this conventional approach is limited to edge coupling, which is susceptible to facet contamination during dicing and substrate attachment. Additionally, this method cannot compensate for package warpage, which negatively impacts optical performance of the photonic devices.

Accordingly, the inventors have developed the systems and methods described herein to overcome these limitations and enable the attachment of top dies without obstructing the V-grooves or coupling cavities, thereby facilitating the integration of pluggable couplers in multi-die and multi-reticle scenarios. In some embodiments, EICs may be attached to the PIC on a side opposite the waveguide side of the PIC. The EICs may be attached to the PIC using a reflow process (e.g., mass reflow or thermocompression bonding) and then molded over. As the EICs are on the opposite side of the PIC as the waveguides, molding over the EICs does not block any optical coupling components (e.g., V-grooves or coupling cavities) as is the case in the conventional devices described above.

The photonic devices described herein and methods of manufacturing thereof provide a number of benefits over conventional photonic devices and their manufacture. For example, the techniques described herein enable a removably couplable optical assembly, enabling easy replacement of defective or damaged components. Further, the techniques may be compatible with wafer-level assembly, which allows for high volume production. The wafer-level processes may further result in lower optical loss than conventional devices and their manufacture due to low warpage, as compared to conventional package level attachment processes. Further, optical sorting and testing of the electro-optical assemblies or die stacks is possible prior to attaching the assembly to the substrate, enabling defective or damaged stacks to be avoided before final formation of the photonic devices.

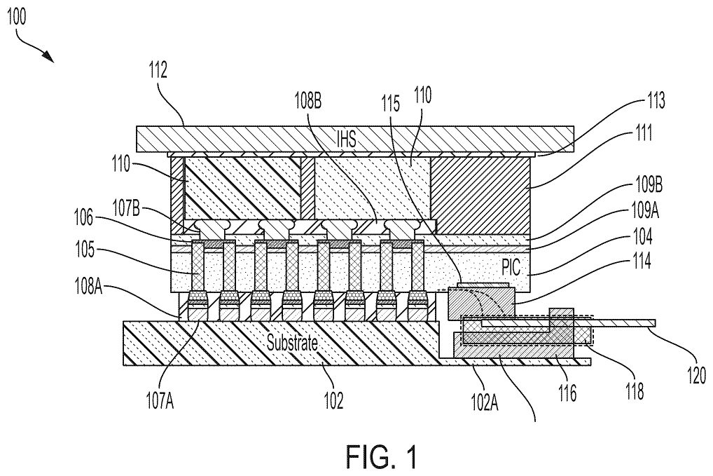

FIG. 1 illustrates a cross-sectional side view of a packaged photonic device 100, according to some embodiments. In the illustrated embodiment, photonic device 100 includes a substrate 102. Substrate 102 may be a printed circuit board (PCB) or an organic substrate, for example. Substrate 102 is configured to route signals generated inside the package to external devices and vice versa and provide structural support for the packaged photonic device.

A photonic integrated circuit (PIC) 104 is disposed on the substrate 102, with a first surface of the PIC 104 facing the substrate 102 and a second surface opposite the first surface. The PIC 104 may be attached to the substrate 102 in any suitable manner, including for example, bumps 107A (e.g., solder bumps). In some embodiments, an underfill 108A may be employed to fill the gap between PIC 104 and substrate 102. In some embodiments, underfill 108A may be made of an adhesive such as epoxy or capillary underfill.

The PIC 104 may include through-silicon vias (TSVs) 105 that extend through the PIC 104 to provide electrical pathways through various layers of the photonic device. In some embodiments, PIC 104 may be active in nature in that it may include modulators, photodetectors and/or optical switches. In one example, PIC 104 may be equipped with optical switches to route data to (and from) other devices. PIC 104 may further include a network of waveguides (not shown). In some embodiments, PIC 104 is made of silicon and PIC waveguides may be made of silicon and/or silicon nitride. In some embodiments, the PIC waveguides are formed in PIC 104 adjacent to the first surface.

One or more electronic integrated circuits (EICs) 110 may be coupled to the PIC 104 at the second surface to form an electro-optical assembly. The EICs 110 may be attached to the PIC 104 through bumps 107B, which may comprise solder bumps or copper pillar interconnects or other suitable attachment mechanism. In the illustrated embodiment, EICs 110 are disposed entirely over PIC 104. However, the technology is not limited in this manner and EICs 110 may partially hang over an edge PIC 104. Underfill 108B may be disposed between the EICs 110 and the PIC 104 to secure the connection and provide mechanical stability. As with underfill 108A, underfill 108B may be made of an adhesive such as epoxy or capillary underfill.

In some embodiments, a redistribution layer may be disposed between the PIC 104 and EIC(s) 110. The RDL may include RDL traces 106 that extend between the TSVs 105 to route electrical signals. The RDL may be formed using physical vapor deposition (PVD), lithography, and plating processes. In some embodiments, the RDL traces 106 may be formed of copper, aluminum, or other conductive materials suitable for routing electrical signals. The RDL traces 106 may be configured to fan out electrical connections from the TSVs 105 to a larger pitch suitable for bump attachment, thereby facilitating electrical interconnection between the PIC 104 and EICs 110 or between the PIC 104 and substrate 102. In some embodiments, the RDL may include multiple metal layers separated by dielectric materials to accommodate complex routing patterns. The RDL traces 106 may route power, ground, and data signals between various components of the photonic device 100. In some embodiments, to facilitate the RDL, one or more passivation layers 109A and 109B may be used to provide protection, electrical insulation, and reduce capacitance between different conductive structures of the photonic device.

In the illustrated embodiment, a pair of EICs 110 are disposed on PIC 104, although any other suitable number of EICs per PIC may be used. The TSVs 105 may be configured to place PIC 104 in electrical communication with EICs 110. Each EIC 110 may include input/output (I/O) circuitry, processing circuitry and/or memory circuitry (not shown). The I/O circuitry may include serializers/deserializers (SerDes), for example. The processing circuitry may be implemented as a central processing unit (CPU), a graphics processing unit (GPU), a field programmable gate array (FPGA), a tensor processing unit (TPU), an accelerator, etc. The memory circuitry may be implemented as a high-bandwidth memory (HBM), for example. Collectively, the ASICs may form a computer system including multiple I/O chips, processing chips and/or multiple memory chips that are optically interconnected with one another through PICs.

An encapsulation structure 111 may at least partially surround the EICs 110 to protect the components from external agents. Encapsulation structure 111 may be made of a molding compound (e.g., epoxy), for example, although other materials may be used. In some embodiments, EICs 110 may sit within a recess of encapsulation structure 111. Conventional photonic devices employing encapsulation structures run into issues as the encapsulation structure typically prevents access to the PIC waveguides. However, photonic device 100 includes the EICs 110 and encapsulation structure 111 on an opposite side of the PIC as the waveguides and optical coupling components. This enables access to the optical coupling components without the need to expose the waveguides and optical coupling components through additional etching or grinding steps that may otherwise damage the photonic devices.

An integrated heat spreader (IHS) 112 may be coupled to the EICs 110 to provide thermal management for the assembly. Accordingly, in some embodiments, encapsulation structure 111 may be ground or etched to expose at least one surface of EIC(s) 110 (e.g., a surface facing away from substrate 102). The IHS 112 may contact exposed surfaces of the EICs 110 to facilitate heat dissipation during operation of the photonic device. In some embodiments, a thermal interface material (TIM) 113 may be disposed between IHS 112 and the exposed surfaces of EICs 110.

In the illustrated embodiment, photonic device 100 further includes an optical coupler 114 disposed on the first surface of the PIC 104, which faces the substrate 102. In some embodiments, optical coupler 114 is disposed within a recess or cavity formed on the first surface of PIC 104. The optical coupler 114 may be secured within the cavity using adhesive 115. In some embodiments, the adhesive may comprise an index-matching adhesive (e.g., index-matching epoxy) to reduce optical losses at the interface.

The optical coupler 114 is configured to direct light between waveguides in the PIC 104 and an optical fiber 120 of an optical assembly. Optical coupler 114 may include any suitable optical coupling components to couple the PIC waveguides with optical fiber 120 when the optical assembly is coupled to the electro-optical assembly. The optical coupling components may include, but are not limited to, diffraction gratings or other grating couplers, lenses, mirrors, or other optical coupling components.

The optical assembly may include an optical coupling component 118 and optical fiber 120. Optical coupling component 118 may include an array of V-grooves or U-grooves-V-shaped or U-shaped channels that have been etched on a substrate to hold fibers in place. In some embodiments, optical coupling component 118 includes a fiber array unit configured to couple one or more optical fibers 120 to the electro-optical assembly. In some embodiments, the optical assembly may be configured to be removably couplable with the electro-optical assembly. For example, optical coupling component 118 may be configured to be pluggable or otherwise removably engage with components of photonic device 100. In that way, defective or damaged components of photonic device 100 may be easily replaceable.

In some embodiments, a socket 116 is disposed adjacent to the first surface of the PIC 104. In the illustrated embodiment, socket 116 is disposed on substrate extension 102A of substrate 102. Substrate extension 102A may form a cavity in the substrate in which socket 116 may be disposed. However, in some embodiments, substrate 102 may not include substrate extension 102A and socket 116 may be otherwise disposed. For example, in some embodiments, socket 116 may be disposed on an edge of substrate 102, on optical coupler 114, on the first surface of PIC 104, or integrated directly with optical coupler 114.

The socket 116 is configured to receive an optical assembly having optical coupling component 118 (e.g., a fiber array unit) and one or more optical fibers 120. When the optical assembly is engaged with the socket 116, the optical fiber 120 is optically coupled to the optical coupler 114, which in turn couples light to and from the waveguides of the PIC 104.

This configuration positions the EICs 110 on the opposite side of the PIC 104 from the optical coupling components, allowing optical coupler 114 to remain accessible for pluggable optical connections while supporting multi-reticle manufacturing processes. For example, as discussed above, in conventional photonic devices, forming the encapsulation structure when the EICs and waveguides are on the same side of the PIC may block access for an optical assembly to the PIC waveguides. As such, conventional photonic devices may require additional manufacturing steps including etching or grinding the encapsulation structure to reveal the waveguides, increasing the risk of damage to various components of the photonic devices.

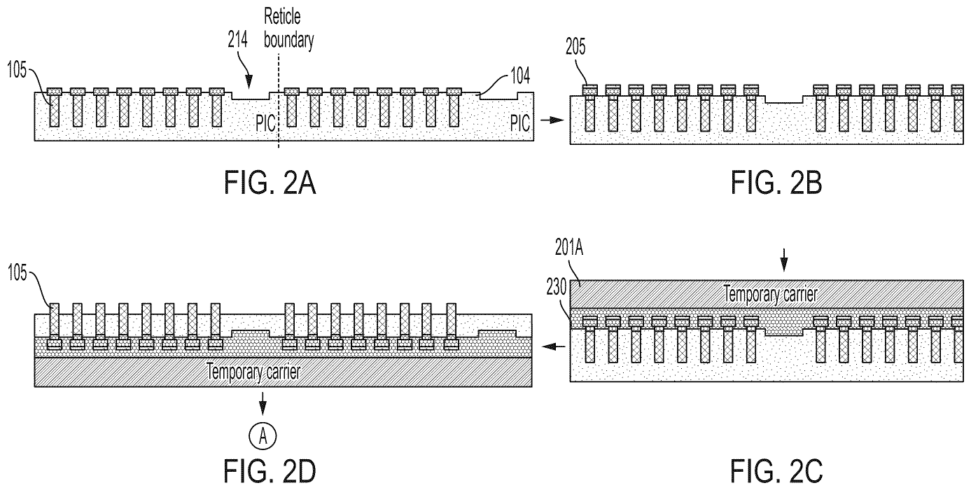

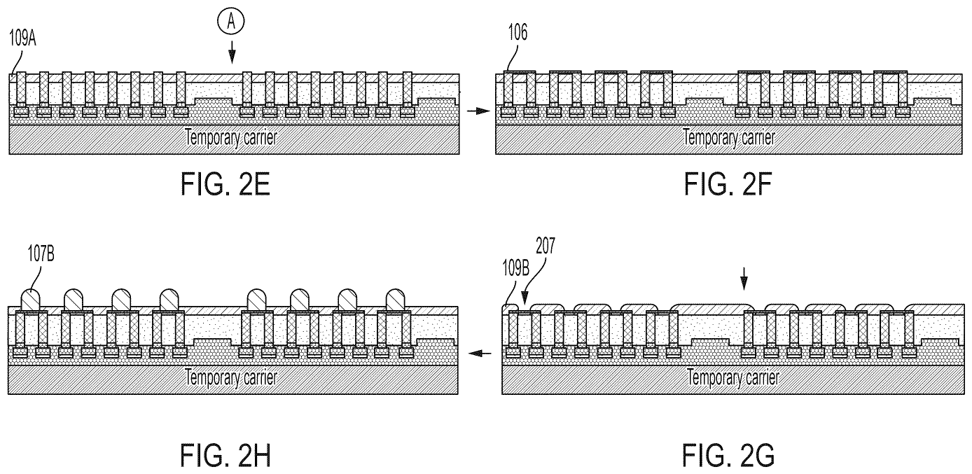

FIGS. 2A-2H illustrate an example process for forming the photonic integrated circuit (PIC) of a photonic device, according to some embodiments.

Referring to FIG. 2A, a PIC 104 is received. In the illustrated embodiment, PIC 104 comprises two reticles as indicated by the PIC boundary. However, PIC 104 may include any suitable number of reticles. In some embodiments, PIC 104 may include one or more recesses 214 for optical coupler attachment. The recess 214 may be etched into the PIC 104 and configured to receive an optical coupler. The PIC 104 includes TSVs 105 extending through (or partially through) the PIC 104. In some embodiments, the PICs may include recesses 214 configured to receive an optical coupler (e.g., optical coupler 114). Accordingly, in some embodiments, the PICs may be obtained from a foundry with the recesses having already been formed in the PIC. Alternatively, in some embodiments, obtaining the PIC comprises forming the recesses in the PIC in house using etching techniques. The recesses may be formed in any suitable manner, including, but not limited to, dry etching, wet etching, or anisotropic etching, as described herein.

Referring to FIG. 2B, pads are attached to provide access to the ends of the TSVs 105 at the first surface of the PIC 104. The pads may be formed using physical vapor deposition (PVD), lithography, and plating techniques, or any other suitable technique.

Referring to FIG. 2C, a first temporary carrier 201A is attached to the PIC 104. The first temporary carrier 201A may be bonded to the surface of the PIC 104 having the recess 214 to provide mechanical support during subsequent processing steps. Adhesive 230 may be used to bond the surfaces. In some embodiments, the adhesive 230 comprises an epoxy or a temporary adhesive. The first temporary carrier 201A may be formed of any suitable material including, for example, silicon.

Referring to FIG. 2D, the PIC 104 is etched to reveal the other side of the TSVs 105 near the second surface of PIC 104. This TSV reveal process may include thinning the PIC 104 from the second surface, e.g., the side opposite the first temporary carrier 201A and etching to expose ends of the TSVs 105. In some embodiments, dry etching may be used to expose the ends of the TSVs, although other etching or grinding processes may be used.

Referring to FIG. 2E, a first passivation layer 109A is formed on the etched surface of the PIC 104. In some embodiments, the passivation layer 109A may comprise an intermediate dielectric layer (IDL) material to provide insulation and reduce capacitance between conductive layers. In some embodiments, the passivation layer 109A and may be planarized using chemical mechanical polishing (CMP).

Referring to FIG. 2F, a redistribution layer (RDL) is deposited on the passivation layer. The RDL may include RDL traces 106 that extend between the TSVs 105 to route electrical signals. The RDL may be formed using PVD, lithography, and plating processes.

Referring to FIG. 2G, a second passivation layer 109B is formed over the RDL. The second passivation layer 109B may be formed (e.g., during deposit or subsequent etching) to include pad openings 207 to expose portions of the RDL traces 106. For example, the pad openings 207 may be formed to expose the portions of the RDL traces for subsequent bump formation.

Referring to FIG. 2H, bumps 107A are disposed on the PIC 104 to be placed in electrical contact with the RDL traces 106. For example, bumps 107A may be disposed in pad openings 207 to be placed physically on the RDL traces 106. The bumps 107A may be formed using PVD, lithography, and plating techniques. The bumps 107A may comprise solder bumps or copper pillar interconnects configured to provide electrical connections to EICs in subsequent assembly steps.

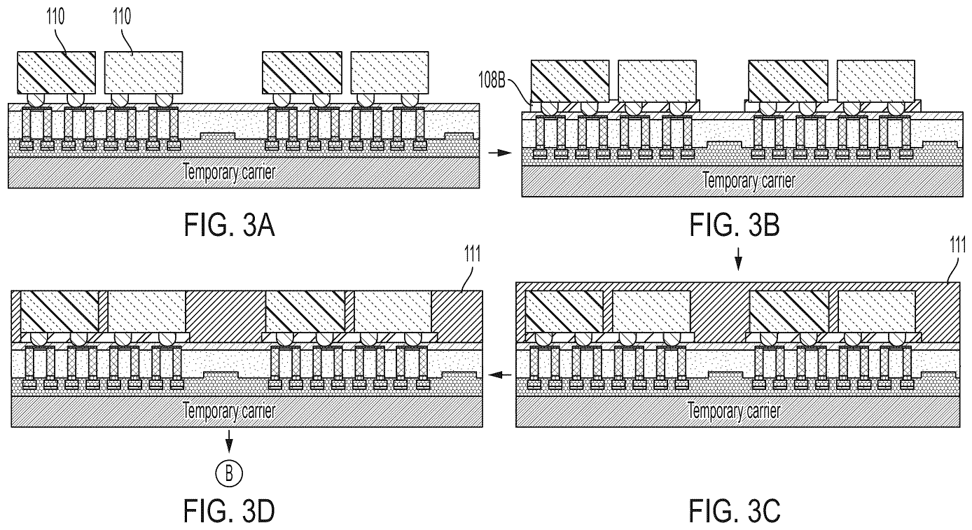

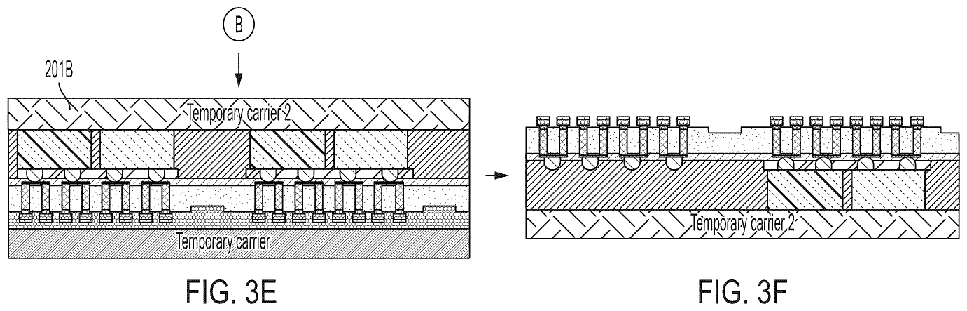

FIGS. 3A-3F illustrate an example process for forming an electro-optical assembly of a photonic device, according to some embodiments.

Referring to FIG. 3A, one or more EICs 110 are coupled to a PIC 104 to form an electro-optical assembly. PIC 104 may be formed according, for example, using the process illustrated in FIGS. 2A-2H. The EICs 110 may be attached to the second surface of the PIC 104 using a reflow process such as mass reflow or thermocompression bonding (TCB). The EICs 110 may be physically and/or electrically connected to the PIC 104 through the bumps 107A, which provide electrical pathways to the TSVs 105. Bumps 107A may be disposed on the exposed ends of TSVs 105 to physically and electrically couple PIC 104 to EICs 110. In the illustrated embodiment, EICs 110 are disposed entirely over PIC 104. However, the technology is not limited in this manner and EICs 110 may partially hang over PIC 104.

Referring to FIG. 3B, underfill 108A is applied between the EICs 110 and the PIC 104. The underfill 108A may be dispensed and cured to secure the mechanical connection between the EICs 110 and the PIC 104 and to protect the electrical interconnections from environmental contamination and other factors.

Referring to FIG. 3C, an encapsulation structure is deposited to at least partially surround the EICs 110. The encapsulation structure may comprise a molding compound that is applied over the EICs 110 and cured. Because the EICs 110 are attached to the second surface of the PIC 104, which is opposite the first surface having the recess 214, the molding process does not obstruct the recess 214 or other optical coupling features on the first surface.

Referring to FIG. 3D, the encapsulation structure is ground to reveal surfaces of the EICs 110 facing away from the PIC 104. For example, this post-mold grinding process may expose the EICs 110 to facilitate thermal management in subsequent steps (e.g., by enabling thermal coupling with a heat spreader).

Referring to FIG. 3E, a second temporary carrier 201B is attached to the electro-optical assembly. The second temporary carrier 201B may be bonded to the ground surface (e.g., by an adhesive, not shown) of the encapsulation structure and the exposed surfaces of the EICs 110 to provide mechanical support during subsequent processing. As with the first temporary carrier, second temporary carrier 201B may be formed of silicon, although other materials may be used.

Referring to FIG. 3F, the first temporary carrier 201A is removed from the PIC 104 of the electro-optical assembly. This debonding step may include cleaning to remove adhesive residue of adhesive from the first surface of the PIC 104, thereby exposing the recess 214 for optical coupler attachment.

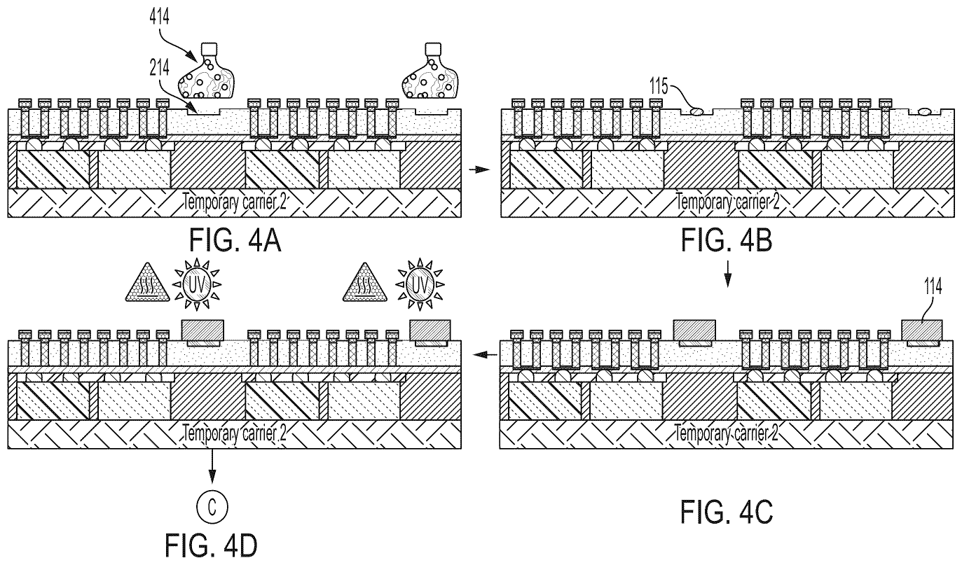

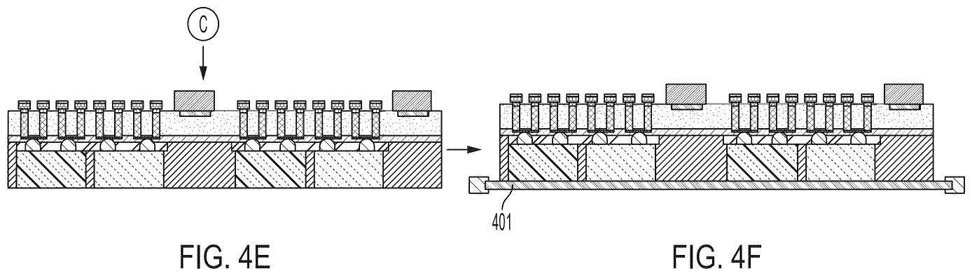

FIGS. 4A-4F illustrate an example process for optical coupler attachment to the electro-optical assembly formed by the process of FIGS. 3A-F, according to some embodiments.

Referring to FIG. 4A, the recess 214 of the PIC 104 is cleaned. The cleaning process may comprise plasma cleaning using plasma cleaning source 414 to remove contaminants and adhesive residue from within the recess 214. Plasma cleaning may prepare the surfaces for improved adhesion in subsequent steps.

Referring to FIG. 4B, adhesive 115 is dispensed within the recess 214. The adhesive 115 may comprise an index-matching adhesive (e.g., index-matching epoxy) configured to reduce optical losses at the interface between the optical coupler and the waveguides of the PIC 104.

Referring to FIG. 4C, an optical coupler 114 is attached to the PIC 104 within the recess 214. The optical coupler 114 may be placed into the recess 214 and positioned to align with waveguides in the PIC 104. The optical coupler 114 may be configured to optically couple the waveguides of the PIC 104 and an optical assembly and direct light between the waveguides and an optical fiber of the optical assembly. In some aspects, the optical coupler 114 may comprise optical coupling components including, but not limited to, grating couplers, waveguides, lenses, mirrors, or other components that redirect light to facilitate coupling with the optical assembly. For example, the PIC waveguides may terminate at an out-of-plane grating coupler configured to direct light from the waveguide out of the first surface of PIC 104 to the optical assembly.

Referring to FIG. 4D, the adhesive 115 is cured to secure the optical coupler 114 within the recess 214. The curing process may include ultraviolet (UV) curing, thermal curing, or a combination thereof. The cured adhesive 115 may provide mechanical stability for the optical coupler 114 while maintaining optical properties at the interface.

Referring to FIG. 4E, the second temporary carrier 201B is removed from the electro-optical assembly. This debonding step may expose the encapsulation structure and the surfaces of the EICs 110 for subsequent processing. Cleaning may be performed to remove adhesive residue from the exposed surfaces.

Referring to FIG. 4F, the electro-optical assembly is attached to a mount for subsequent dicing. The mount may comprise dicing tape 401 configured to hold the assembly during singulation. As noted above, in some embodiments, the assembly of the photonic devices up to this stage may be performed at the wafer level, with the wafer containing multiple electro-optical assemblies that are to be diced into individual units.

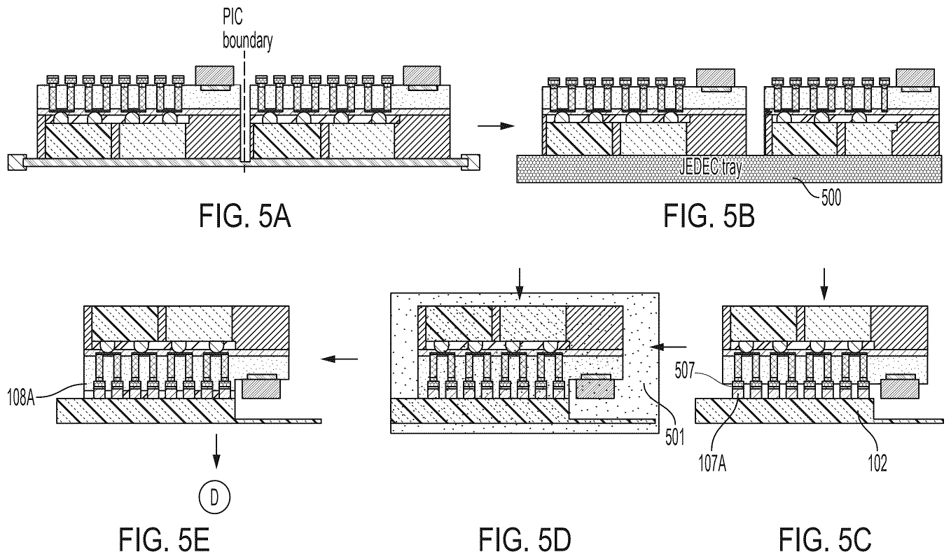

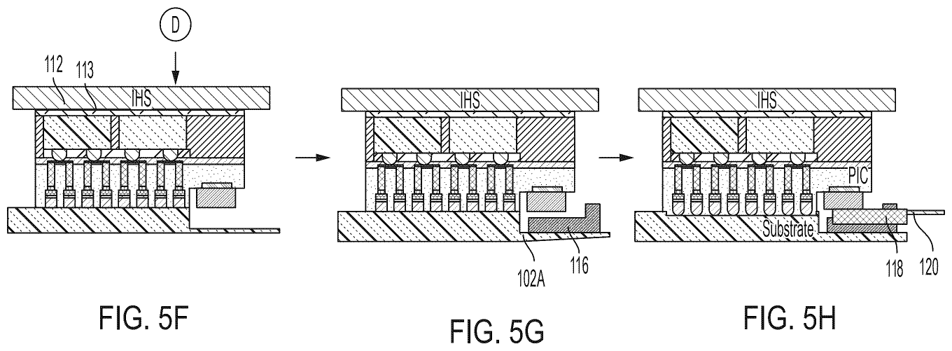

FIGS. 5A-5H illustrate an example process for forming photonic devices having electro-optical assemblies formed by processes of FIGS. 4A-F, according to some embodiments.

Referring to FIG. 5A, individual electro-optical assemblies are diced from a wafer containing multiple assemblies. The dicing process may singulate the wafer along boundary lines (e.g., reticle boundary lines of FIG. 2A) to separate the individual electro-optical assemblies. Because the optical coupler 114 is attached prior to dicing, the waveguides and optical coupling interfaces may be protected from contamination that could otherwise occur during the dicing process.

Referring to FIG. 5B, the individual electro-optical assemblies are loaded onto a matrix tray 500. The matrix tray 500 may comprise a JEDEC tray or similar carrier configured to hold multiple assemblies for subsequent processing and handling. The assemblies may be transferred from the dicing mount to the matrix tray using pick and place equipment.

Referring to FIG. 5C, the individual electro-optical assemblies are attached to a substrate 102. The attachment may be performed using mass reflow or thermocompression bonding (TCB). The bumps 107A on the first surface of the PIC 104 may be bonded to corresponding pads 507 on the substrate 102 to establish electrical connections between the electro-optical assembly and the substrate 102.

Referring to FIG. 5D, a cleaning step is performed to remove solder flux and other manufacturing by-products from the assemblies. The deflux cleaning process 501 may remove residues that could otherwise affect the reliability or performance of the photonic device 100.

Referring to FIG. 5E, underfill 108A (e.g., epoxy, capillary underfill) is applied between the PIC 104 and the substrate 102. The underfill 108A may be dispensed and cured to secure the mechanical connection between the electro-optical assembly and the substrate 102 and to protect the electrical interconnections.

Referring to FIG. 5F, an integrated heat spreader (IHS) 112 is attached to the electro-optical assemblies. The IHS 112 may be coupled to the exposed surfaces of the EICs 110 to provide thermal management during operation of the photonic device 100. In some embodiments, a TIM layer 113 is disposed between IHS 112 and EICs 110.

Referring to FIG. 5G, a socket 116 configured to receive an optical assembly is attached to an electro-optical assembly. The socket 116 may be disposed adjacent the first surface of the PIC 104. For example, socket 116 may be mounted on the substrate extension 102A as illustrated. However in some embodiments, socket 116 may be otherwise disposed adjacent the first surface of PIC 104 including, but not limited, on an edge of substrate 102, on PIC 104, on optical coupler 114, or integrated with optical coupler 114. The socket 116 may provide a mechanical interface for receiving an optical assembly and enable removable coupling between the optical assembly and electro-optical assembly.

Referring to FIG. 5H, an optical assembly having an optical coupling component 118 having an optical fiber 120 is optically coupled to the optical coupler 114. The optical coupling component 118 may comprise a pluggable fiber array unit (FAU) that is inserted into the socket 116. When the optical assembly is engaged with the socket 116, the optical fiber 120 is aligned with and optically coupled to the optical coupler 114, which directs light between the optical fiber 120 and the waveguides of the PIC 104. The pluggable configuration may allow the optical assembly to be removed and replaced without disassembling the photonic device 100.

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, and/or methods described herein, if such features, systems, articles, materials, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than described, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.” The phrase “and/or,” as used herein in the specification and in the claims, should be understood to mean “either or both” of the elements so conjoined, i.e., elements that are conjunctively present in some cases and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “approximately” and “about” may be used to mean within +20% of a target value in some embodiments, within ±10% of a target value in some embodiments, within ±5% of a target value in some embodiments, and yet within ±2% of a target value in some embodiments. The terms “approximately” and “about” may include the target value.

What is claimed is:

1. A photonic device, comprising:
a substrate;
an electro-optical assembly comprising:
a photonic integrated circuit (PIC) disposed on the substrate, the PIC having a first surface facing the substrate and a second surface opposite the first surface;
an electronic integrated circuit (EIC) coupled to the PIC at the second surface;
an optical assembly having an optical fiber; and
an optical coupler disposed on the first surface of the PIC configured to optically couple the electro-optical assembly with the optical fiber when the optical assembly is coupled with the electro-optical assembly.

2. The photonic device of claim 1, wherein the optical coupler is secured within a cavity on the first surface of the PIC with index-matching adhesive.

3. The photonic device of claim 1, further comprising an encapsulation structure at least partially surrounding the EIC.

4. The photonic device of claim 1, wherein the optical assembly is configured to be removably couplable from the electro-optical assembly.

5. The photonic device of claim 4, further comprising a socket disposed adjacent the first surface of the PIC, wherein the optical assembly is configured to be removably couplable from the electro-optical assembly by engaging with the socket to optically couple the optical fiber with the optical coupler.

6. The photonic device of claim 5, wherein the socket is disposed on the electro-optical assembly.

7. The photonic device of claim 5, wherein the socket is disposed on the substrate.

8. The photonic device of claim 1, further comprising an integrated heat spreader coupled with the EIC.

9. The photonic device of claim 1, wherein the optical assembly comprises a pluggable fiber array unit.

10. A method for manufacturing a photonic device, the method comprising:
receiving a photonic integrated circuit (PIC), the PIC having a first surface and a second surface opposite the first surface;
forming an electro-optical assembly by coupling an electronic integrated circuit (EIC) to the PIC at the second surface;
securing an optical coupler to the first surface;
securing the electro-optical assembly to a substrate at the first surface; and
coupling an optical assembly to the electro-optical assembly, the optical assembly having an optical fiber, wherein the optical coupler is configured to optically couple the optical fiber to the electro-optical assembly when the optical assembly is coupled with the electro-optical assembly.

11. The method of claim 10, wherein forming the electro-optical assembly comprises:
etching the PIC at the second surface to expose ends of through silicon vias (TSVs) extending through the PIC; and
disposing conductive bumps at the exposed ends of the TSVs, wherein the EIC is coupled with the PIC via the conductive bumps.

12. The method of claim 11, wherein forming the electro-optical assembly further comprises:
forming a redistribution layer comprising conductive traces extending between the TSVs; and
disposing the conductive bumps on the redistribution layer.

13. The method of claim 10, wherein forming the electro-optical assembly further comprises:
forming an encapsulation structure to at least partially surround the EIC.

14. The method of claim 13, wherein forming the electro-optical assembly further comprises:
grinding the encapsulation structure to expose a surface of the EIC facing away from the PIC; and
attaching a heat sink to the exposed surface of the EIC.

15. The method of claim 10, wherein securing the optical coupler to the first surface comprises:
disposing adhesive within a cavity on the first surface;
placing the optical coupler within the cavity; and
curing the adhesive.

16. The method of claim 15, wherein securing the optical coupler to the first surface further comprises:
plasma cleaning at least the cavity on the first surface prior to disposing the adhesive within the cavity.

17. The method of claim 10, wherein coupling an optical assembly to the electro-optical assembly comprises:
removably coupling the optical assembly to the electro-optical assembly.

18. The method of claim 17, wherein removably coupling the optical assembly to the electro-optical assembly comprises:
inserting the optical assembly into a socket disposed on the substrate.

19. The method of claim 10, wherein forming the electro-optical assembly comprises:
forming a plurality of electro-optical assemblies as an integrated wafer.

20. The method of claim 19, wherein forming the electro-optical assembly further comprises:
dicing the integrated wafer to obtain individual electro-optical assemblies.
